(19) United States
(12) Patent Application Publication
(10) Pub. No.: US 2026/0285673 A1
(43) Pub. Date: Sep. 24, 2026

(54) INTEGRATED DEVICE AND MANUFACTURING METHOD THEREOF

(71) Applicant: Taiwan Semiconductor Manufacturing Company, Ltd., Hsinchu (TW)

(72) Inventors: Hsi-Cheng Hsu, Hsinchu (TW); Jui-Chun Weng, Hsinchu (TW); Shin-Hua Chen, Hsinchu (TW); Yu-Fan Lin, Hsinchu (TW); Ji-Hong Chiang, Hsinchu (TW)

(73) Assignee: Taiwan Semiconductor Manufacturing Company, Ltd., Hsinchu (TW)

(21) Appl. No.: 19/088,271

(22) Filed: Mar. 24, 2025

(51) Int. Cl. B81B 7/02; B81C 1/00; G01L 1/14

(52) U.S. Cl. CPC B81B 7/02; B81C 1/00341; G01L 1/142; B81B 2201/025; B81B 2201/0264; B81B 2203/0163; B81B 2203/04; B81B 2207/092

(57) ABSTRACT

An integrated device includes a motion sensor and a pressure sensor. The motion sensor and the pressure sensor are disposed on the substrate and arranged side by side. The motion sensor and the pressure sensor are integrated into the integrated device, the monolithically integrated device including motion sensor and pressure sensor is realized. The present invention may not only scale down chip size by integrating a plurality of discrete devices, but also provide a prompt electrical signal transmission between the two sensors.

### BACKGROUND

MEMS sensors are commonly used in sensing systems, and the most widely-used type is consumer electronics such as smartphones. In general, a plurality of sensors are manufactured separately and then disposed on a printer circuit board (PCB) in order.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic diagram of an integrated device according to an embodiment of the present disclosure;

FIG. 1B illustrates a schematic diagram of a cross-sectional view of the integrated device in FIG. 1A along a direction 1B-1B′; and

FIGS. 2A to 2N illustrate schematic diagrams of manufacturing processes of the integrated device in FIG. 1B.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

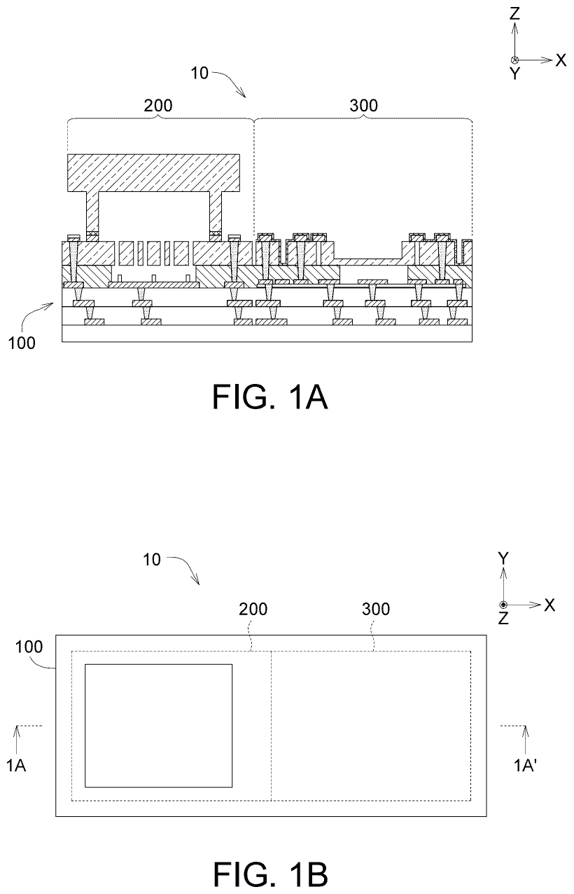

Referring to FIGS. 1A and 1B, FIG. 1A illustrates a schematic diagram of an integrated device 10 according to an embodiment of the present disclosure, and FIG. 1B illustrates a schematic diagram of a cross-sectional view of the integrated device 10 in FIG. 1A along a direction 1B-1B′. The integrated device 10 is, for example, a MEMS (Micro Electro-Mechanical Systems) device.

The integrated device 10 includes a substrate 100, a motion sensor 200 and a pressure sensor 300. The motion sensor 200 and the pressure sensor 300 are disposed on the substrate 300. The motion sensor 200 and the pressure sensor 300 share the substrate 100 and arranged side by side. In the present embodiment, the motion sensor 200 and the pressure sensor 300 are integrated into the same integrated device 10, and the integrated device 10 has at least one of the following technical advantages: (1). small packaging area compared to two separated sensors; (2). prompt electrical signal transmission relies on monolithic microchip; (3). shared process may be used to reduce costs.

The motion sensor 200 may detect the posture of the integrated device 10, and the pressure sensor 300 may detect an air pressure of ambience outside the integrated device 10.

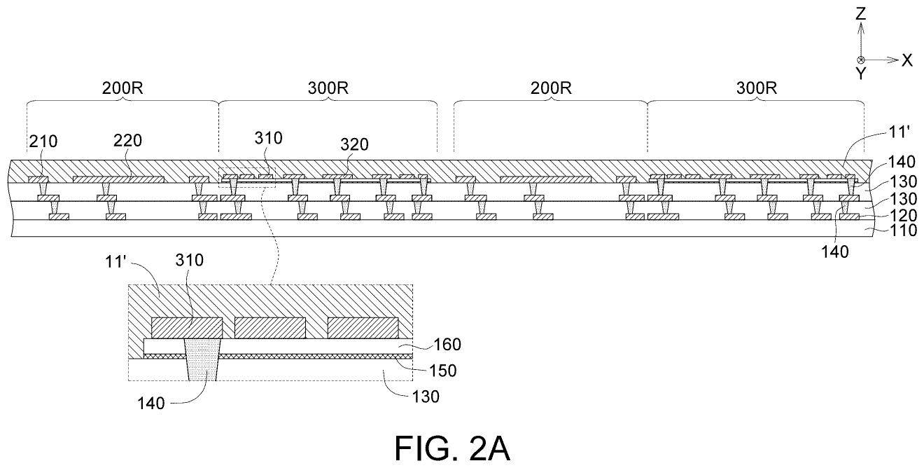

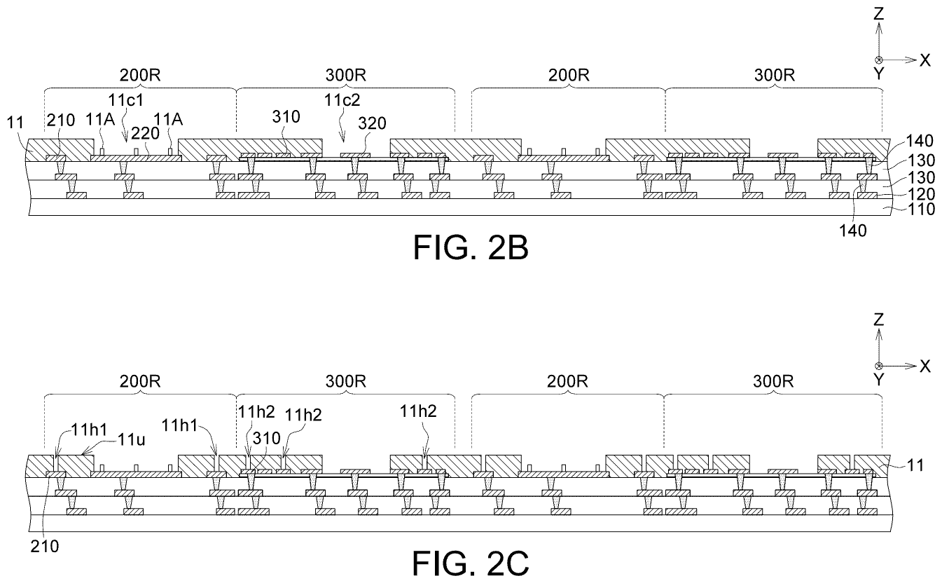

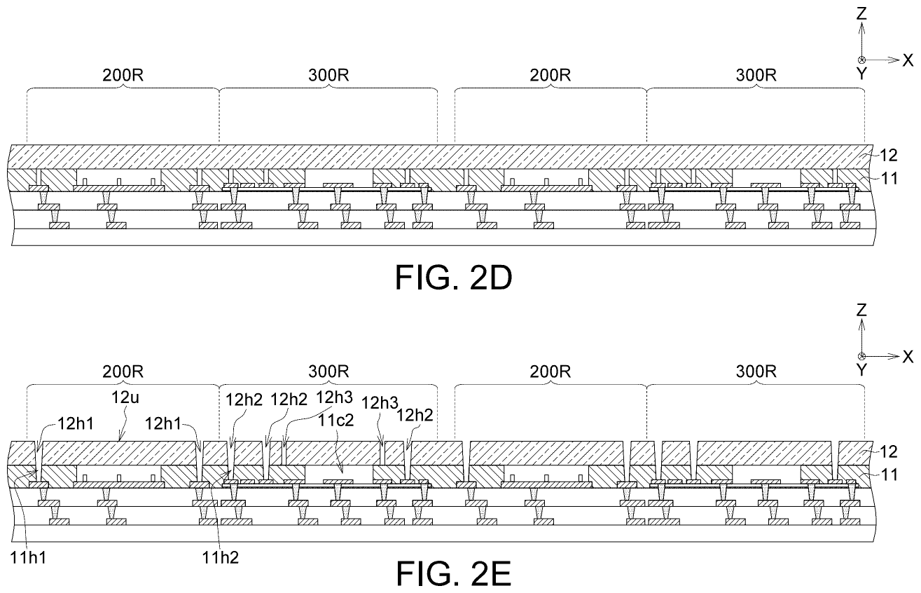

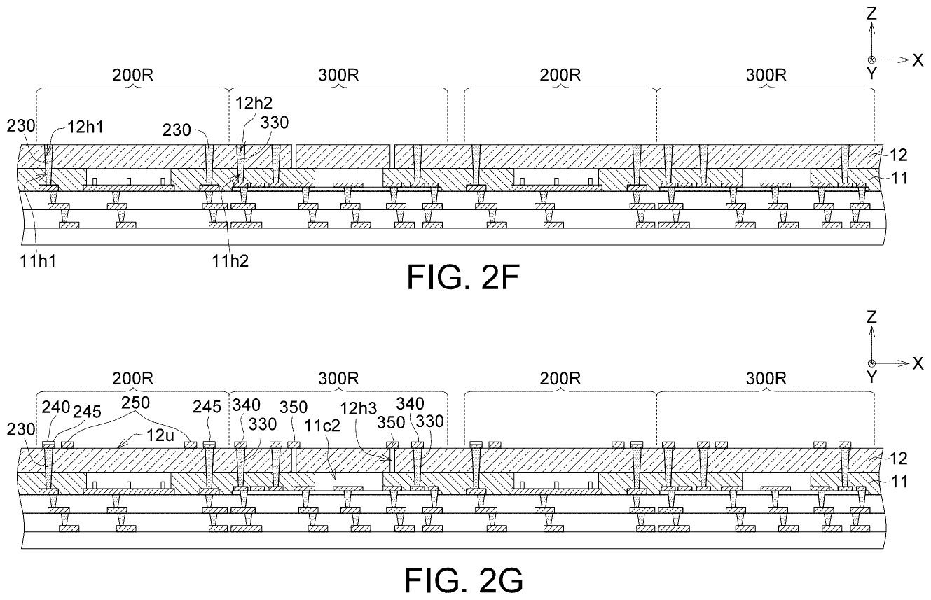

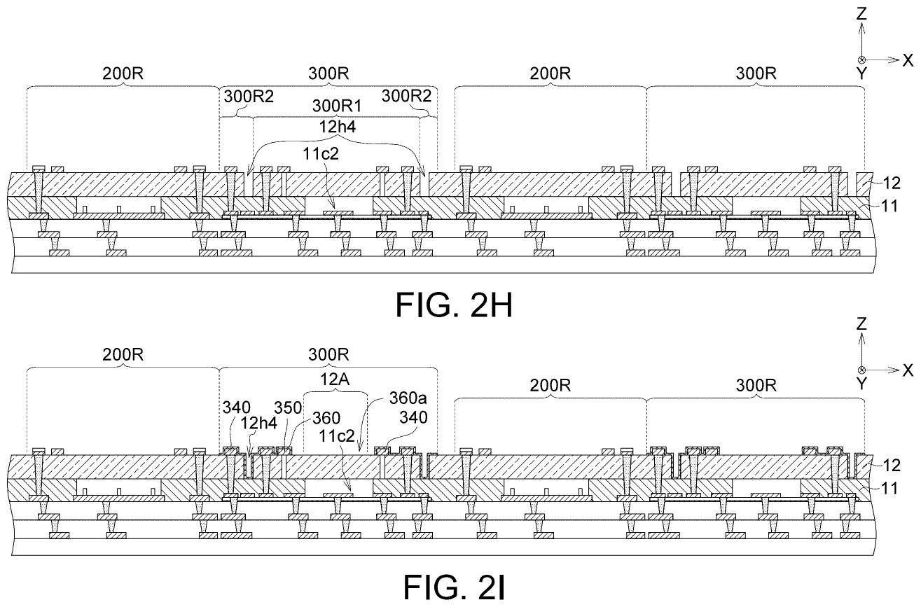

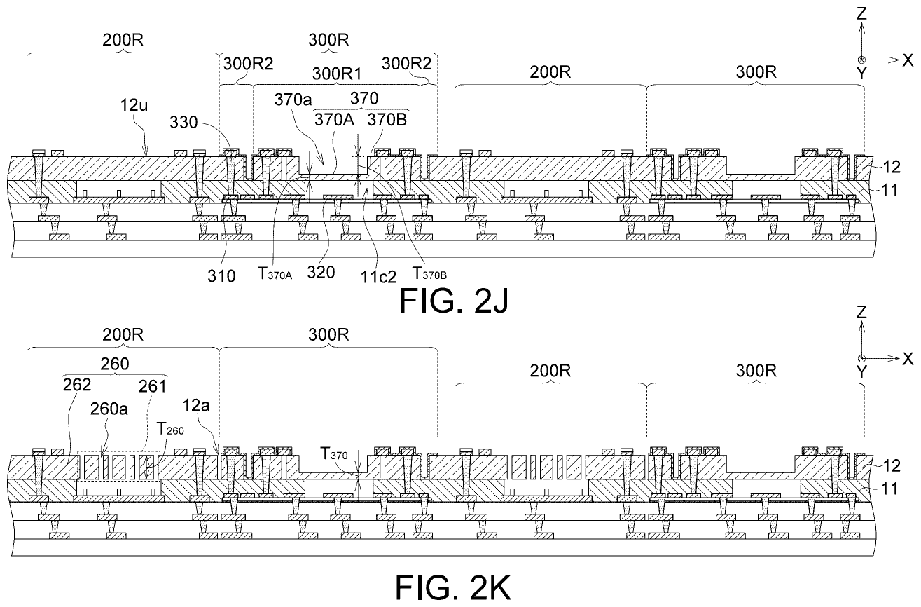

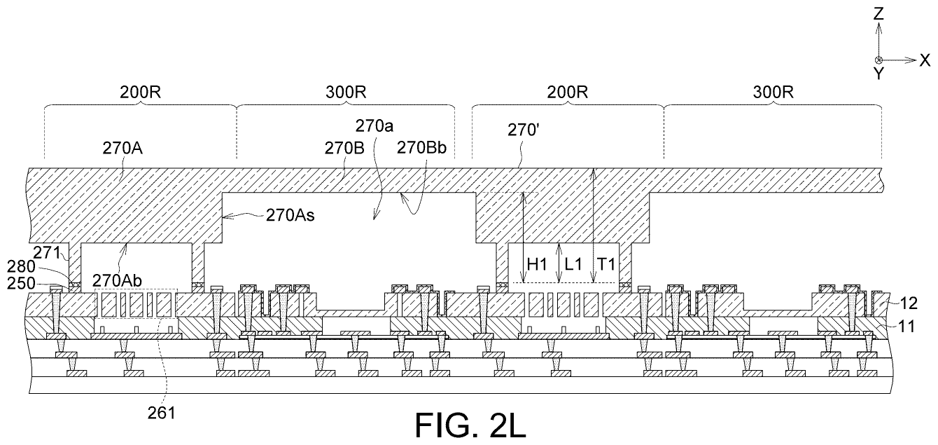

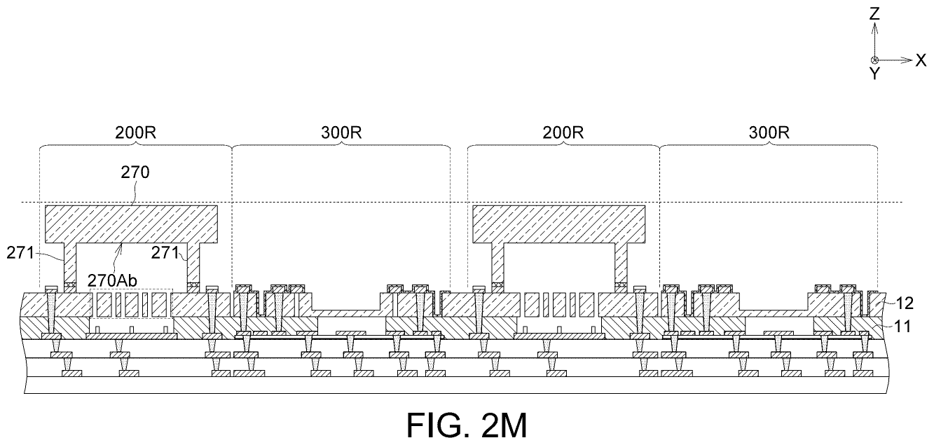

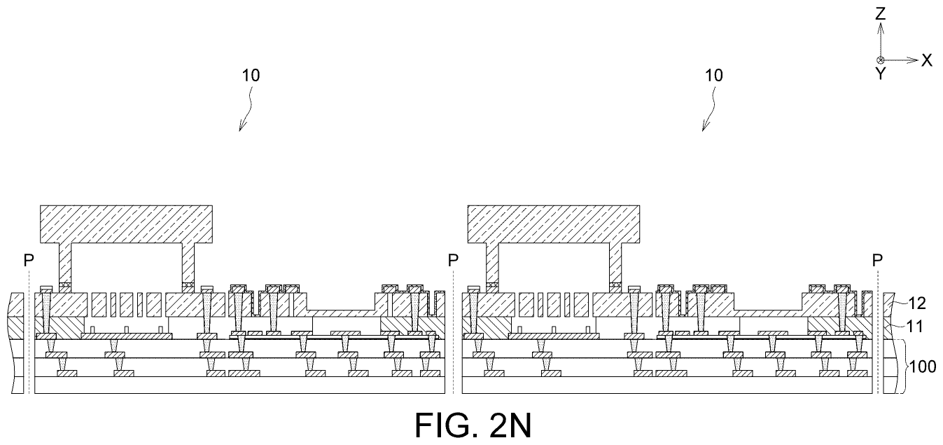

Referring to FIGS. 2A to 2N, FIGS. 2A to 2N illustrate schematic diagrams of manufacturing processes of the integrated device 10 in FIG. 1B.

As illustrated in FIG. 2A, the substrate 100 is formed. The substrate 100 includes a base 110, a plurality of conductive traces 120, a plurality of dielectric layers 130, a plurality of conductive vias 140, a barrier layer 150 and a covering layer 160. The base 110 includes, for example, a portion of a silicon wafer and at least one transistor (not illustrated) formed in the silicon wafer. One or some of the conductive traces 120 is disposed on the base 110 and covered by one of the dielectric layers 130. Another or some of the conductive traces 120 is disposed on the dielectric layer 130, and covered by another of the dielectric layers 130. The conductive via 140 connects the conductive traces 120 on the upper and lower dielectric layers 130. The barrier layer 150 is disposed between the dielectric layer 130 and the covering layer 160 and configured to block the moisture. In an embodiment, the barrier layer 150 is formed of, for example, silicon nitride (SiN). The dielectric layers 130 may be formed of, for example, oxide. One of some of the conductive vias 140 may penetrate the dielectric layer 130, the barrier layer 150 and the covering layer 160. In addition, a motion sensor region 200R and a pressure sensor region 300R may be defined in the substrate 100.

Then, as illustrated in FIG. 2A, at least one first conductive pad 210, at least one first lower electrode 220, at least one second conductive pad 310, at least one second lower electrode 320 are formed on the topmost dielectric layer 130 of the substrate 100 by using, for example, electroplating, photolithography, etching, etc. The first conductive pads 210 and the first lower electrode 220 are formed in the motion sensor region 200R, and the second conductive pads 310 and the second lower electrode 320 are formed in the pressure sensor region 300R. The second conductive pad 310 is electrically connected with the second lower electrode 320, and the first conductive pads 210 is electrically connected with the first lower electrode 220. The first conductive pads 210, the first lower electrode 220, the second conductive pads 310 and the second lower electrode 320 are formed by patterning a conductive material layer in the same process. In addition, the first conductive pad 210, the first lower electrode 220, the second conductive pad 310 and the second lower electrode 320 are formed of the same material, for example, aluminum, copper or an alloy combination.

As illustrated in FIG. 2A, an insulation material 11′ covering the first conductive pads 210, the first lower electrode 220, the second conductive pads 310 and second lower electrode 320 is formed by using, for example, deposition. The insulation material 11′ is formed of an inter-metal-dielectric (IMD), for example, oxide.

As illustrated in FIG. 2B, the insulation material 11′ in FIG. 2A is patterned to form an insulation layer 11 first cavity 11c1 and a second cavity 11c2 by, for example, photolithography, etching, etc., wherein the insulation layer 11 includes a first cavity 11c1 and a second cavity 11c2, the first cavity 11c1 exposes the first lower electrode 220, and the second cavity 11c2 exposes the second lower electrode 320. After the insulation material 11′ is patterned, the remained portion of the insulation material 11′ form at least one stop portion 11A, wherein the stop portion 11A is disposed on the first lower electrode 210 and exposed from the first cavity 11c1. In the present embodiment, the stop portions 11A are formed in the process of patterning the insulation layer 11. The stop portions 11A, the first cavity 11c1 and the second cavity 11c2 are formed in the same process. In addition, the first cavity 11c1 and the stop portions 11A are located in the motion sensor region 200R, and the second cavity 11c2 is located in the pressure sensor region 300R.

As illustrated in FIG. 2C, at least first through hole 11h1 and at least second through hole 11h2 passing through the insulation layer 11 are formed by photolithography, etching, etc. The first through holes 11h1 are formed in the motion sensor region 200R, and the second through holes 11h2 are formed in the pressure sensor region 300R. The first through holes 11h1 extend to the first conductive pad 210 from an upper surface 11u of the insulation layer 11, and the second through holes 11h2 extend to the second conductive pad 310 from the upper surface 11u of the insulation layer 11.

As illustrated in FIG. 2D, a semiconductor layer 12 above the insulation layer 11 by using, for example, fusion bonding or direct bonding. The semiconductor layer 12 and the insulation layer 11 may be in contact with each other, and bonding by a covalent bond interface between the semiconductor layer 12 and the insulation layer 11. The covalent bond may be formed between the semiconductor layer 12 and the insulation layer 11 at a temperature and a pressure. Then, the semiconductor layer 12 may be thinned by using, for example, CMP (chemical mechanical polishing). In an embodiment, the semiconductor layer 12 is, for example, a silicon wafer.

As illustrated in FIG. 2E, at least one third through hole 12h1, at least one fourth through hole 12h2 and at least one fifth through hole 12h3 are formed in the semiconductor layer 12 by using, for example, photolithography, etching, etc. The third through holes 12h1, the fourth through holes 12h2 and the fifth through holes 12h3 are formed in the same process. The third through holes 12h1 are located in the motion sensor region 200R, and the fourth through holes 12h2 and the fifth through holes 12h3 are located in the pressure sensor region 300R. Each third through hole 12h1 extends to the corresponding first through hole 11h1 from an upper surface 12u of the semiconductor layer 12, and each fourth through hole 12h2 extends to the corresponding second through hole 11h2 from the upper surface 12u of the semiconductor layer 12, and the fifth through holes 12h3 extend to the insulation layer 11 from the upper surface 12u of the semiconductor layer 12. Although not illustrated, the fifth through hole 12h3 may be connected with the second cavity 11c2 for vacuuming the second cavity 11c2.

As illustrated in FIG. 2F, at least first conductive portion 230 within the first through hole 11h1 and the third through hole 12h1 are formed by, for example, electroplating, photolithography, etching, etc. At least second conductive portion 330 within the second through hole 11h2 and the fourth through hole 12h2 are formed by, for example, electroplating, photolithography, etching, etc. The first conductive portion 230 and the second conductive portion 330 are formed in the same process. In addition, the first conductive portions 230 are located in the motion sensor region 200R, and the second conductive portions 330 are located in the pressure sensor region 300R.

As illustrated in FIG. 2G, at least one third conductive pad 240, a connection pad 250, at least one fourth conductive pad 340 and at least one sealing pad 350 are formed by, for example, electroplating, photolithography, etching, etc. The third conductive pad 240 and the connection pad 250 are located in the motion sensor region 200R, and the fourth conductive pad 340 and the sealing pad 350 are located in the pressure sensor region 300R. The third conductive pad 240, the connection pad 250, the fourth conductive pad 340 and the sealing pad 350 may be formed of the same material, for example, aluminum, copper or an alloy combination. The third conductive pad 240 is formed on and electrically connected with the first conductive portion 230. The fourth conductive pad 340 is formed on and electrically connected with the second conductive portion 330. The connection pad 250 is formed on the upper surface 12u of the semiconductor layer 12. In an embodiment, viewed from a top view, the connection pad 250 (or referred to as a bond ring) may be a ring shape, for example, a closed ring-shape or an opened ring-shape. The sealing pad 350 may close (or cover) an opening of the fifth through hole 12h3 after the second cavity 11c2 is vacuumed. The sealing pad 350 closes the opening of the fifth through hole 12h3, and thus the vacuum state of the second cavity 11c2 may be maintained.

As illustrated in FIG. 2G, at least one protective layer 245 on the third conductive pad 240 is formed by using, electroplating, photolithography, etching, etc. In an embodiment, the protective layer 245 may be formed of metal, for example, titanium (Ti).

As illustrated in FIG. 2H, at least one separating hole 12h4 passing through the semiconductor layer 12 is formed by using, for example, photolithography, etching, etc. The separating hole 12h4 is located in the pressure sensor region 300R. The separating hole 12h4 divides the semiconductor layer 12 in FIG. 2G into an active zone 300R1 and a non-active zone 300R2, wherein the active zone 300R1 and the second cavity 11c2 overlap in Z-axis. Due to the separating hole 12h4, the active zone 300R1 may be a separated portion which may detect an air pressure without being affected by other connected portion, for example, the non-action zone 300R2.

As illustrated in FIG. 2I, a barrier layer 360 covering each fourth conductive pad 340, each sealing pad 350 and a plurality of inner surfaces of each separating hole 12h4 is formed by using, deposition, photolithography, etching, etc. The barrier layer 360 is located in the pressure sensor region 300R. After the barrier layer 360 is patterned, the barrier layer 360 exposes a sensing region 12A defined in the active zone 300R1 corresponding to the second cavity 11c2. In an embodiment, the barrier layer 360 is formed of, for example, silicon nitride (SiN). The barrier layer 360 may block moisture from invading the pressure sensor 300.

As illustrated in FIG. 2J, the semiconductor layer 12 in the active zone 300R1 i thinned to form a second upper electrode 370 by using, for example, photolithography, etching, etc. The second upper electrode 370 is opposite to the second lower electrode 320. The second upper electrode 370 is a portion of the semiconductor layer 12 in the active zone 300R1. In an embodiment, the second upper electrode 370 includes a sensing portion 370A corresponding to the second cavity 11c2 and a connection portion 370B connecting with the sensing portion 370A. Furthermore, the second upper electrode 370 has a recess 370a recessed relative to the upper surface 12u of the semiconductor layer 12 to form the sensing portion 370A. An air pressure may cause a deformation of the sensing portion 370A along Z-axis to change a distance between the sensing portion 370A and the second lower electrode 320 along Z-axis, and accordingly a capacitance between the sensing portion 370A and the second lower electrode 320 is changed, and a corresponding signal (for example, current, voltage) may be generated and then transmitted through the second lower electrode 320, the second conductive pad 310 and the second conductive portion 330.

In FIG. 2J, the sensing portion 370A has a thickness T_{370A}, and the connection portion 370B has a thickness T_{370B}, wherein the thickness T_{370A} is less than the thickness T_{370B}. For example, the thickness T_{370A} of the sensing portion 370A may range between, for example, 8 micrometers and 12 micrometers, for example, 10 micrometers, etc., while the thickness T_{370B} of the connection portion 370B the second upper electrode 370 ranges between, for example, 20 micrometers and 35 micrometers, for example, 25 micrometers, 30 micrometers.

As illustrated in FIG. 2K, the semiconductor layer 12 is patterned to form at least one at least one through hole 260a and at least one separating slot 12a by using, for example, photolithography, etching, etc. After the semiconductor layer 12 is patterned, the semiconductor layer 12 in the motion sensor region 200R form a first upper electrode 260 including a spring structure 261 and a connection portion 262 connected with the spring structure 261. The aforementioned connection pad 250 is disposed on the first upper electrode 260. The spring structure 261 has at least one through hole 260a to form a flexible structure or a deformable structure for detecting a motion of the integrated device 10, for example, an orientation or a posture relative to XYZ coordinate system. In addition, the separating slot 12a may separate the first upper electrode 260 in the motion sensor region 200R from the second upper electrode 370 in the pressure sensor region 300R for preventing the electrical signal of the motion sensor region 200R and the electrical signal of the pressure sensor region 300R from interfering with each other. In addition, when a deformation of the spring structure 261 occurs along X-axis, a corresponding signal (for example, current, voltage) may be generated and then transmitted through the first conductive pad 210, the first lower electrode 220 and the first upper electrode 260.

In an embodiment, the first upper electrode 260 has a thickness (first thickness) T₂₆₀, wherein the thickness T₂₆₀ of the first upper electrode 260 is substantially equal to the thickness (second thickness) T_{370B} of the connection portion 370B of the second upper electrode 370 in FIG. 2J, and the thickness T₂₆₀ of the first upper electrode 260 is greater than the thickness (third thickness) T_{370A} of the sensing portion 370A. In an embodiment, the thickness T₂₆₀ of the first upper electrode 260 of the second upper electrode 370 may range between, for example, 20 micrometers and 35 micrometers, for example, 25 micrometers, 30 micrometers, etc.

As illustrated in FIG. 2L, a cap plate 270′ is disposed above the semiconductor layer 12. The cap plate 270′ includes at least one cap portion 270A, at least one connection portion 270B and at least one post 271, wherein each cap portion 270A covers the corresponding motion sensor region 200R, the connection portion 270B is connected with a lateral surface 270Ab of the cap portion 270A, the cap portion 270A protrudes relative to a lower surface 270Bb of the connection portion 270B, and the post 271 is connected with a lower surface 270Ab of the cap portion 270A and protrudes relative to the lower surface 270Ab of the cap portion 270A. The cap plate 270′ has at least one recess 270a, and the recess 270a is recessed relative to the lower surface 270Ab of the cap portion 270A. Viewed from a top view, the post 271 may be a ring shape, for example, a closed ring-shape or an opened ring-shape.

In the present embodiment, the connection layer 280 is formed on an end surface of the post 271 in advance. In other words, before disposing the cap plate 270′ above the semiconductor layer 12, the connection layer 280 is formed on the end surface of the post 271. In an embodiment, the cap plate 270′ is, for example, a silicon wafer which is patterned, and the connection layer 280 is formed of a semiconductor material, for example, Germanium (Ge), etc., wherein the connection layer 280 may be formed on the end surface of the post 271 by using, epitaxy process. The cap plate 270′ may connect the connection pad 250 by the connection layer 280, and the connection layer 280 may increase the combination between the connection pad 250 and the post 271. In addition, the first cavity 11c1 and the spring structure 261 are closed among the cap portion 270A and the post 271, the connection layer 280 and the connection pad 250, and thus it may prevent the impurities from invading the first cavity 11c1 and the spring structure 261.

In the present embodiment, the cap plate 270′ has a thickness T1 along Z-axis, the post 271 has a length L1 along Z-axis, and there is a distance H1 between the lower surface 270Bb the connection portion 270B along Z-axis. In an embodiment, the thickness T1 is, for example, 725 micrometers. The distance H1 is greater than the length L1. For example, the length L1 is, for example, 50 micrometers, and the distance H1 is, for example, 150 micrometers.

As illustrated in FIG. 2M, a portion of the cap portion 270A, the entirety of the connection portion 270B of the cap plate 270′ are removed by using, for example, CMP. After CMP, a remained portion of the cap plate 270′ forms at least one cap 270 and at least one post 271, wherein the post 271 is connected with the lower surface 270Ab of the cap portion 270A and protrudes relative to the lower surface 270Ab of the cap portion 270A.

As illustrated in FIG. 2N, at least one singulation P1 passing through the insulation layer 11 and the semiconductor layer 12 by using, for example, sawing tool. After singulation, at least one integrated device 10 including the motion sensor 200 and the pressure sensor 300 disposed on the substrate 100 is formed.

In FIG. 2N, the motion sensor 200 at least includes the first conductive pad 210, the first lower electrode 220, the first conductive portion 230, the third conductive pad 240, the protective layer 245, the connection pad 250, the first upper electrode 260, the cap 270, the connection layer 280, the insulation layer 11 and the semiconductor layer 12. The pressure sensor 300 at least includes the second conductive pad 310, the second lower electrode 320, the second conductive portion 330, the fourth conductive pad 340 and the sealing pad 350, the barrier layer 360, the second upper electrode 370, the insulation layer 11 and the semiconductor layer 12.

As described above, the motion sensor 200 and the pressure sensor 300 are simultaneously formed on the substrate 100.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, an integrated device includes a motion sensor and a pressure sensor. The motion sensor and the pressure sensor are disposed on the substrate and arranged side by side. The motion sensor and the pressure sensor are integrated into the integrated device, the monolithically integrated device including motion sensor and pressure sensor is realized. The present invention may not only scale down chip size by integrating a plurality of discrete devices, but also provide a prompt electrical signal transmission between the two sensors.

Example embodiment 1: an integrated device includes a substrate, a motion sensor and a pressure sensor. The motion sensor and the pressure sensor are disposed on the substrate. The motion sensor and the pressure sensor share the substrate and arranged side by side.

Example embodiment 2 based on Example embodiment 1: the motion sensor includes a first upper electrode, the pressure sensor includes a second upper electrode, and the first upper electrode and the second upper electrode are separated from each other.

Example embodiment 3 based on Example embodiment 1: the motion sensor includes a first upper electrode, the pressure sensor includes a second upper electrode, the first upper electrode has a first thickness, the second upper electrode has a second thickness and a third thickness, and the second thickness and the first thickness substantially are equal and the third thickness is less than the second thickness.

Example embodiment 4 based on Example embodiment 1: the motion sensor includes a first upper electrode having a thickness, and the pressure sensor further includes a second upper electrode having an upper surface and a recess recessed relative to the upper surface to form a sensing portion. The sensing portion has a thickness less than the thickness of the first upper electrode.

Example embodiment 5 based on Example embodiment 1: the pressure sensor includes a lower electrode, an upper electrode and a sealing pad. The lower electrode is disposed on the structure. The upper electrode is disposed opposite to the lower electrode and has a through hole. The sealing pad covers an opening of the through hole.

Example embodiment 6 based on Example embodiment 5: the motion sensor further includes a lower electrode, an upper electrode, a connection pad, a cap and a connection layer. The lower electrode is disposed on the structure. The upper electrode is disposed opposite to the lower electrode of the motion sensor and has a spring structure. The connection pad is disposed on the upper electrode. The cap is connected with the upper electrode and covers the spring structure. The connection layer connects the cap with the connection pad.

Example embodiment 7 based on Example embodiment 5: the motion sensor includes a lower electrode, an upper electrode and a connection pad. The lower electrode is disposed on the structure. The upper electrode is disposed opposite to the lower electrode of the motion sensor. The connection pad is disposed on the upper electrode. The connection pad and the sealing pad are formed of the same material.

Example embodiment 8 based on Example embodiment 7: the connection pad is a bond ring.

Example embodiment 9 based on Example embodiment 7: the motion sensor further includes a cap connected with the connection pad and covering a portion of the upper electrode.

Example embodiment 10 based on Example embodiment 1: the motion sensor further includes an upper electrode and a cap. The upper electrode is disposed above the substrate and has a spring structure. The cap is connected with the upper electrode and covering the spring structure.

Example embodiment 11: a manufacturing method for an integrated device includes the following steps: providing a substrate; and simultaneously forming a motion sensor and a pressure sensor on the substrate, wherein the motion sensor and the pressure sensor share the substrate and arranged side by side. Forming the motion sensor and the pressure sensor on the substrate includes: forming an insulation layer on the substrate, wherein the insulation layer has a first cavity of the motion sensor and a second cavity of the pressure sensor.

Example embodiment 12 based on Example embodiment 11: simultaneously forming the motion sensor and the pressure sensor on the substrate further includes: forming a first lower electrode of the motion sensor and a second lower electrode of the pressure sensor on the substrate.

Example embodiment 13 based on Example embodiment 12: in forming the insulation layer on the substrate, the first cavity exposes the first lower electrode, and the second cavity exposes the second lower electrode.

Example embodiment 14 based on Example embodiment 13: simultaneously forming the motion sensor and the pressure sensor on the substrate further includes: forming a stop portion on the first lower electrode.

Example embodiment 15 based on Example embodiment 11: simultaneously forming the motion sensor and the pressure sensor on the substrate further includes: forming a first upper electrode of the motion sensor above the structure; and forming a second upper electrode of the pressure sensor above the structure. The first upper electrode and the second upper electrode are separated from each other.

Example embodiment 16 based on Example embodiment 11: simultaneously forming the motion sensor and the pressure sensor on the substrate further includes: forming a first upper electrode of the motion sensor above the structure; forming a second upper electrode of the pressure sensor above the structure; and forming a recess in the second upper electrode, wherein the second upper electrode has an upper surface, the recess is recessed relative to the upper surface to form a sensing portion, and the sensing portion has a thickness is less than a thickness of the first upper electrode.

Example embodiment 17: a manufacturing method for an integrated device includes the following steps: providing a substrate having a surface; and forming a motion sensor and a pressure sensor on the surface of the substrate, including: forming a first lower electrode and a second lower electrode on the surface of the substrate; forming a semiconductor layer above the insulation layer; patterning the semiconductor layer to form a first upper electrode and a second upper electrode; and forming a recess in the second upper electrode.

Example embodiment 18 based on Example embodiment 17: the second upper electrode has an upper surface, the recess is recessed relative to the upper surface to form a sensing portion, and the sensing portion has a thickness is less than the thickness of the first upper electrode.

Example embodiment 19 based on Example embodiment 17: forming the motion sensor and the pressure sensor on the substrate further including: disposing a cap plate above the semiconductor layer, wherein the cap plate includes a cap portion and a connection portion connected with the cap portion, the cap portion covers a motion sensor region, and the connection portion covers a pressure sensor region; and removing entirety of the connection portion.

Example embodiment 20 based on Example embodiment 19: the cap plate further includes a post disposed a lower surface of the cap portion; forming the motion sensor and the pressure sensor on the substrate further including: before disposing the cap plate above the semiconductor layer, forming a connection layer on an end surface of the post.

Example embodiment 21: a monolithically integrated device including a plurality of sensors is realized. In an embodiment, the sensors may be disposed on or formed on a substrate of the integrated device side by side during at least one semiconductor process.

Example embodiment 22: a manufacturing method for an integrated device includes the following steps: providing a substrate; and simultaneously forming a motion sensor and a pressure sensor on the substrate, wherein the motion sensor and the pressure sensor share the substrate and arranged side by side.

Example embodiment 23 based on Example embodiment 22: simultaneously forming the motion sensor and the pressure sensor on the substrate further includes: forming a first lower electrode of the motion sensor and a second lower electrode of the pressure sensor on the substrate.

Example embodiment 24 based on Example embodiment 23: simultaneously forming the motion sensor and the pressure sensor on the substrate further includes: forming an insulation layer on the substrate, wherein the insulation layer has a first cavity of the motion sensor and a second cavity of the pressure sensor, wherein the first cavity exposes the first lower electrode, and the second cavity exposes the second lower electrode.

Example embodiment 25 based on Example embodiment 24: simultaneously forming the motion sensor and the pressure sensor on the substrate further includes: forming a stop portion on the first lower electrode.

Example embodiment 26 based on Example embodiment 22: simultaneously forming the motion sensor and the pressure sensor on the substrate further includes: forming a first upper electrode of the motion sensor above the structure; and forming a second upper electrode of the pressure sensor above the structure. The first upper electrode and the second upper electrode are separated from each other.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated device, comprising:
a substrate;
a motion sensor on the substrate; and
a pressure sensor on the substrate;
wherein the motion sensor and the pressure sensor share the substrate and arranged side by side.

2. The integrated device as claimed in claim 1, wherein the motion sensor comprises first upper electrode, the pressure sensor comprises a second upper electrode, and the first upper electrode and the second upper electrode are separated from each other.

3. The integrated device as claimed in claim 1, wherein the motion sensor comprises first upper electrode, the pressure sensor comprises a second upper electrode, the first upper electrode has a first thickness, the second upper electrode has a second thickness and a third thickness, and the second thickness and the first thickness substantially are equal and the third thickness is less than the second thickness.

4. The integrated device as claimed in claim 1, wherein the motion sensor comprises first upper electrode having a thickness, and the pressure sensor further comprises:
a second upper electrode having an upper surface and a recess recessed relative to the upper surface to form a sensing portion;
wherein the sensing portion has a thickness less than the thickness of the first upper electrode.

5. The integrated device as claimed in claim 1, wherein the pressure sensor comprises:
a lower electrode on the structure;
an upper electrode disposed opposite to the lower electrode and having a through hole; and
a sealing pad covering an opening of the through hole.

6. The integrated device as claimed in claim 5, wherein the motion sensor further comprises:
a lower electrode on the structure;
an upper electrode disposed opposite to the lower electrode of the motion sensor and having a spring structure;
a connection pad on the upper electrode;
a cap connected with the upper electrode and covering the spring structure; and
a connection layer connecting the cap with the connection pad.

7. The integrated device as claimed in claim 5, wherein the motion sensor comprises:
a lower electrode on the structure;
an upper electrode disposed opposite to the lower electrode of the motion sensor; and
a connection pad on the upper electrode;
wherein the connection pad and the sealing pad are formed of the same material.

8. The integrated device as claimed in claim 7, wherein the connection pad is a bond ring.

9. The integrated device as claimed in claim 7, wherein the motion sensor further comprises:
a cap connected with the connection pad and covering a portion of the upper electrode.

10. The integrated device as claimed in claim 1, wherein the motion sensor further comprises:
an upper electrode above the substrate and having a spring structure; and
a cap connected with the upper electrode and covering the spring structure.

11. A manufacturing method for an integrated device, comprising:
providing a substrate; and
simultaneously forming a motion sensor and a pressure sensor on the substrate, wherein the motion sensor and the pressure sensor share the substrate and arranged side by side;
wherein forming the motion sensor and the pressure sensor on the substrate comprising:
forming an insulation layer on the substrate, wherein the insulation layer has a first cavity of the motion sensor and a second cavity of the pressure sensor.

12. The manufacturing method as claimed in claim 11, wherein simultaneously forming the motion sensor and the pressure sensor on the substrate further comprises:
forming a first lower electrode of the motion sensor and a second lower electrode of the pressure sensor on the substrate.

13. The manufacturing method as claimed in claim 12, wherein in forming the insulation layer on the substrate, the first cavity exposes the first lower electrode, and the second cavity exposes the second lower electrode.

14. The manufacturing method as claimed in claim 13, wherein simultaneously forming the motion sensor and the pressure sensor on the substrate further comprises:
forming a stop portion on the first lower electrode.

15. The manufacturing method as claimed in claim 11, wherein simultaneously forming the motion sensor and the pressure sensor on the substrate further comprises:
forming a first upper electrode of the motion sensor above the structure; and
forming a second upper electrode of the pressure sensor above the structure;
wherein the first upper electrode and the second upper electrode are separated from each other.

16. The manufacturing method as claimed in claim 11, wherein simultaneously forming the motion sensor and the pressure sensor on the substrate further comprises:
forming a first upper electrode of the motion sensor above the structure;
forming a second upper electrode of the pressure sensor above the structure; and
forming a recess in the second upper electrode, wherein the second upper electrode has an upper surface, the recess is recessed relative to the upper surface to form a sensing portion, and the sensing portion has a thickness is less than a thickness of the first upper electrode.

17. A manufacturing method for an integrated device, comprising:
providing a substrate having a surface; and
forming a motion sensor and a pressure sensor on the surface of the substrate, comprising:
forming a first lower electrode and a second lower electrode on the surface of the substrate;
forming a semiconductor layer above the substrate;
patterning the semiconductor layer to form a first upper electrode and a second upper electrode; and
forming a recess in the second upper electrode.

18. The manufacturing method as claimed in claim 17, wherein the second upper electrode has an upper surface, the recess is recessed relative to the upper surface to form a sensing portion, and the sensing portion has a thickness is less than the thickness of the first upper electrode.

19. The manufacturing method as claimed in claim 17, wherein forming the motion sensor and the pressure sensor on the substrate further comprises:
disposing a cap plate above the semiconductor layer, wherein the cap plate comprises a cap portion and a connection portion connected with the cap portion, the cap portion covers a motion sensor region, and the connection portion covers a pressure sensor region; and
removing entirety of the connection portion.

20. The manufacturing method as claimed in claim 19, wherein the cap plate further comprises a post disposed a lower surface of the cap portion, and forming the motion sensor and the pressure sensor on the substrate further comprises:
before disposing the cap plate above the semiconductor layer, forming a connection layer on an end surface of the post.
